(19) United States
(12) Patent Application Publication
(10) Pub. No.: US 2004/0042289 A1
(43) Pub. Date: Mar. 4, 2004

(54) Integrated memory circuit with a storage element and method for reading error information

(76) Inventors: Manfred Proll, Dorfen (DE); Claus Engelhardt, Munchen (DE); Heinz-Joachim Neubauer, Munchen (DE); Jorg Kliewer, Munchen (DE)

Correspondence Address: LERNER AND GREENBERG, P.A., Post Office Box 2480, Hollywood, FL, 33022-2480, US

(21) Appl. No.: 10/654,715

(22) Filed: Sep. 4, 2003

(30) Foreign Application Priority Data
Sep. 4, 2002 (DE) 102 40 670.7

(51) Int. Cl. G11C 7/00

(52) U.S. Cl. 365/200

(57) ABSTRACT

An integrated memory circuit has a memory cell array and a test circuit. The memory cell array is formed with memory areas each having a number of cells. The test circuit generates error information during testing of an addressed memory area. The error information indicates if at least one of the cells of the addressed memory area is faulty. A storage element is provided which, given the occurrence of an error in the addressed memory area, stores information with the aid of which the faulty memory cell of the faulty area can be identified.

### BACKGROUND OF THE INVENTION

1. Field of the Invention

The invention lies in the memory technology field. More specifically, the invention relates to a memory circuit with a memory cell array and a test circuit whereby error information is generated in the testing of the memory cell array. The invention further relates to a method for testing an integrated memory circuit whereby additional error information about faulty memory areas is supplied.

Integrated memory circuits are tested during and after fabrication. In what is known as a front end test, the integrated memory circuit is repeatedly written with test data and read according to predetermined test patterns. Defective memory areas that are detected are repaired by replacement with normal memory areas that are redundantly provided in the integrated memory circuit. The majority of errors that occur in the integrated memory circuit are single bit errors. Nevertheless, the areas in which the faulty cells are located are replaced with redundant memory areas comprising a plurality of cells.

In the testing process, the error information is transferred from the integrated memory circuit to a tester unit in which a repair solution is calculated. The repair solution indicates how to replace the faulty memory cells or areas with redundant memory areas. That is, given a faulty memory cell, it indicates whether to replace the cell with one or more redundant word lines or one or more redundant bit lines. In order to save test time, many tests are converted to ACTM (Advanced Compression Mode), in which information relating to the failed y-address, the failed data bits, and the data polarity is eliminated. To that end, the error information is already compressed in the integrated memory circuit, so that the only information that is still transferred to the tester unit is the memory area in which the error has occurred. This information comprises the error address of a memory area and can thus no longer contain the precise memory cell address.

It is not necessary to know the exact memory cell address in order to compute the repair solution in the tester unit. Furthermore, the transmission of the exact addresses of the defective memory cells to the tester unit would substantially increase the test duration. For this reason, the information about the address of the faulty memory cell, which is beyond the error information indicating the faulty memory area, is discarded in the integrated memory circuit before the error information is transmitted to the tester unit.

Despite wide-ranging test procedures both in the front end and the back end (after installation of the integrated circuit in a housing), integrated memory modules that are designated as faultless still may comprise errors that are first noted by the consumer subsequent to shipment. These can generally no longer be repaired, and the modules are returned to the manufacturer as being unusable.

In order to improve the production process, particularly the testing methods, it is important to find the cause of error in what is known as a customer return analysis in order to avoid such errors in the future production of memory modules. In order to find the cause of the error, the information about the precise position of the faulty memory cell or cells is needed. However, in previous memory circuits, it has been impossible to determine this position of the faulty memory cell by performing a test, owing to the above-mentioned reduction of the test data that are transmitted.

What are known as hard errors (failure of a memory cell under any condition) can be detected with a probability of 100% by front end and back end testing, because all memory cells are tested with a simple write and read test. The modules that are returned, therefore, mostly have so-called soft errors (errors that occur only under specific conditions). Errors may have also emerged later due to degradation or aging effects. The particular conditions under which the soft errors occur can be simulated only in a special test method. For this reason, the precise position of the faulty memory cell cannot be determined simply by writing data and reading data according to the standard write and read methods for an integrated memory circuit.

Thus, the integrated memory circuit must be tested in a production test system in order to determine the faulty memory area even in a customer return analysis. But such test systems are usually configured only for carrying out conventional front end and back end test methods, and consequently error information can be generated only about faulty memory areas and not about the exact position of faulty memory cells.

The disadvantage here is that it is impossible to acquire essential information that is needed for analyzing the cause of error in the customer return analysis.

### SUMMARY OF THE INVENTION

It is accordingly an object of the invention to provide an integrated memory circuit with a memory element and a method for reading error information, which overcomes the above-mentioned disadvantages of the heretofore-known devices and methods of this general type and which enables a determination of the addresses of faulty cells in finished integrated memory circuits.

With the foregoing and other objects in view there is provided, in accordance with the invention, an integrated memory circuit, comprising:

a memory cell array formed with memory areas each having a plurality of cells; and

a test circuit connected to the memory cell array and configured to generate error information during testing of a respectively addressed memory area, the error information indicating if at least one of the cells of the addressed memory area is faulty;

a storage element for storing information identifying a faulty memory cell of the faulty memory area given an occurrence of an error in the addressed memory area.

With the above and other objects in view there is also provided, in accordance with the invention, a method for testing an integrated memory circuit having a memory cell array and a test circuit, and the cell array having memory areas each encompassing a number of cells. The novel method comprises the following steps:

addressing a memory area for testing the memory cell array;

generating error information indicating whether at least one of the cells of the addressed memory area is faulty; and

storing information identifying a faulty memory cell of the faulty memory area given the occurrence of an error in the addressed memory area.

According to a first aspect of the invention, an integrated memory circuit with a memory cell array and a test circuit is provided. The memory cell array comprises areas, each of which contains a number of memory cells. The test circuit generates error information during testing of an addressed memory area indicating whether at least one of the memory cells of the addressed memory area is faulty and therefore the entire area is faulty. Also provided is a storage element for storing information with the aid of which, given the occurrence of an error in the addressed memory area, the faulty cell of the faulty area is identifiable.

The inventive memory circuit creates the possibility to carry out a testing method, for instance by means of a conventional test system, even on a finished memory module, whereby error information only about faulty memory areas is transferred to the tester unit of the test system. In order to determine which of the cells in the respective faulty area is defective, a storage element that can store this information is provided.

Whereas what are known as hard errors (errors that occur in any write or read operation) are detectable simply by writing and reading data in the integrated memory circuit, what are known as soft errors (errors that occur only under specific conditions) are only detectable by carrying out a testing method with the aid of a test system.

Because a large volume of data is usually transmitted between the integrated memory circuit and the test unit in test procedures, these data must be compressed. For this reason, the information about the faulty memory cell is compressed in the integrated memory circuit so as to generate error information that indicates solely the memory area in which the error has occurred. The area is selected such that, insofar as it is faulty, this area can be replaced with a redundant area of a substantially equal size.

In the customer return analysis, faulty memory modules that have tested normal in the front end and back end testing steps are rechecked with the aim of locating the cause of the error. This is necessary in order to improve the production process so that the relevant error no longer occurs, and also to improve the test procedure for checking the integrated memory circuit for errors, so that this error can be detected even in the front end test procedure.

For this reason, a storage element is inventively provided, for instance a register memory, which expands the redundancy-compliant error information about the faulty memory area so that the exact position of the faulty cell can be determined from the redundancy-compliant error information and the contents of said storage element.

The contents of the storage element advantageously indicate the position of the faulty memory cell within the faulty memory area. If the redundancy-compliant error information represents a compression of 1:16; i.e., 16 memory cells are reproduced in one bit of information, then a representation width of 4 bits is sufficient for the storage element to store information about the position of the memory cell.

The storage element is preferably large enough that it is possible to represent information about the exact cell addresses of a plurality of faulty cells within the area that has been found to be faulty. That way, more than one defective cell within an area can be identified when more than one memory cell in the area is defective.

It can be further provided that the storage element comprises error type information indicating what type of error has occurred in the faulty cell. The error type information can contain an indication as to whether a faulty 0 or a faulty 1 was read in the reading of a data item from a memory cell. This is information that may be required for determining the cause of error, because it can be inferred on the basis of this information whether an unwanted coupling, leakage current, or similar source, has caused the error.

It is expediently provided that the contents of the storage element are readable from the integrated memory circuit, whereby the readout can be carried out according to an externally prescribed signal. That way, it is possible to set a test instruction which allows access to the storage element at signal inputs of the integrated memory circuit, whereby the contents of the storage element are set at data outputs of the integrated memory circuit.

According to another aspect of the invention, a method for testing an integrated memory circuit is provided. In the testing of the cell array, a memory area is addressed, whereby error information is generated indicating whether at least one of the cells of the addressed area is faulty. Given an error in the addressed area, information is stored with the aid of which the faulty cell of the faulty area can be identified.

The advantage of the inventive method is that the error information, which is compressed in a conventional test operation, is expanded by additional information which can be stored in a storage element, for example, so that the exact position or address of the faulty cell can be determined. This is necessary particularly in the customer return analysis and when the faulty cell cannot be detected simply by writing and reading into a memory address because it is a soft error.

Other features which are considered as characteristic for the invention are set forth in the appended claims.

Although the invention is illustrated and described herein as embodied in an integrated memory circuit with a storage element and method for reading error information, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block circuit diagram of an integrated memory circuit according to the invention; and

FIG. 2 is a table illustrating the allocation of the storage element in the integrated memory circuit of FIG. 1.

### DESCRIPTION OF THE PREFERRED EMBODIMENTS

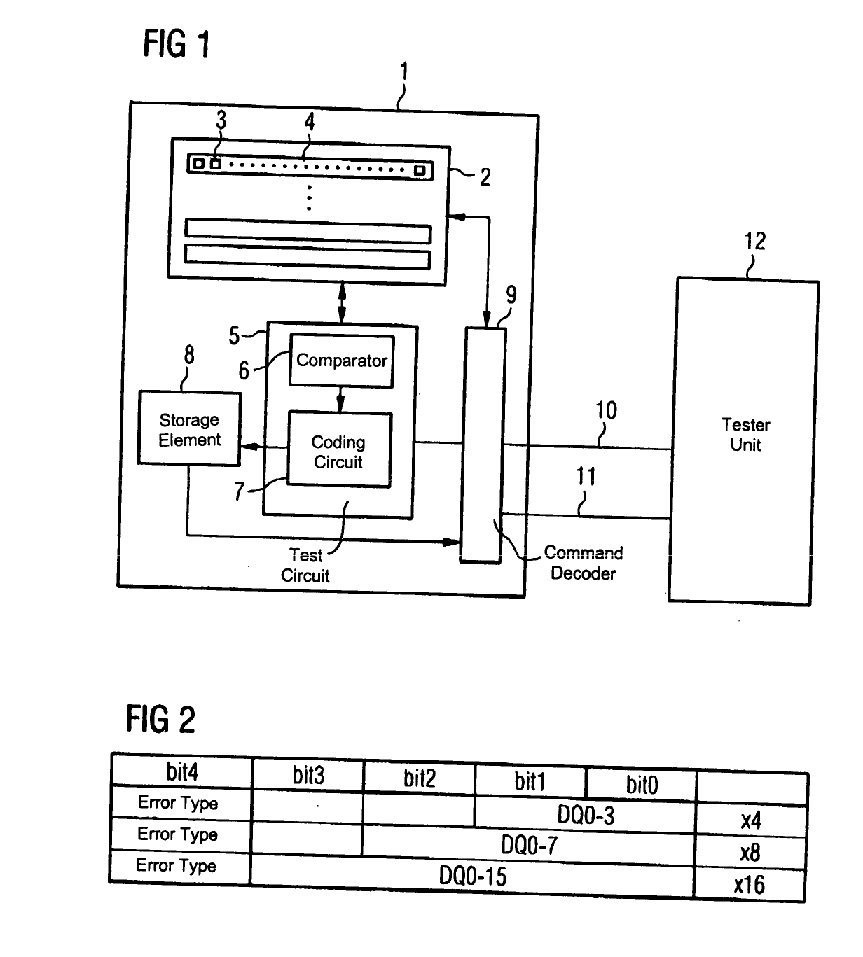

Referring now to the figures of the drawing in detail and first, particularly, to FIG. 1 thereof, there is shown an integrated memory circuit 1 with a memory cell array 2. The cell array 2 comprises cells 3 that are configured in memory areas 4.

The cells 3 of the memory cell array 2 are advantageously DRAM (dynamic random access memory) cells but can also be some other type of cell such as SRAM (synchronous random access memory), or the like. The cells of the DRAM memory cell array 2 are addressed by way of non-illustrated word lines and bit lines.

The memory areas 4 represented in FIG. 1 are cells along a word line. The memory areas can also be formed by memory cells along one or more bit lines, however. The memory areas referenced 4 normally represent areas in the cell array whose cells are addressed by a common word line or lines or by one or more column selection lines with which bit lines can be activated.

A test circuit 5 is connected to the memory cell array 2 for testing the memory cell array 2. The test circuit 5 comprises a comparator circuit 6 which serves for comparing the data that are read from the cell array 2 with the target data—i.e. the data that were previously written into the cell array. The target data are either generated by the circuit internally or supplied by an external tester unit. If the written and read data match, then a logical 0 is generated as pass information; if the data differ, then a logical 1 is generated as error information.

The information thus obtained is compressed in a redundancy-compliant fashion and made available at an output 10 of the integrated memory circuit 1 for transmission to a tester unit 12. The coded error information corresponds to a 1 when an error has occurred at any cell in the memory area just tested. Because the memory area address that has just been tested is known in the external tester unit, with the transmission of the coded error information, the tester unit receives information about the memory area address at which a faulty cell is located.

If the error data received as a result of the comparison in the comparator circuit 6 indicate a faulty memory cell in one of the areas 4, the coding circuit 7 transmits the exact position of the faulty cell to a storage element 8, while that outputs the coded error information to the output of the integrated memory circuit 1. The storage element 8 is expediently constructed as a register and is suitable for storing an address value indicating the position of the faulty cell in the respective faulty memory area 4.

A command decoder 9 is also provided, which is connected to external terminals of the integrated memory circuit 1 in order to decode test commands of input signals at inputs 11 and execute the test functions according to the received commands. A test command is provided which makes possible the reading of the memory cell address from the storage element 8 and the outputting of said address to the external tester device 12 over the output lines 10.

With the memory circuit represented in FIG. 1, it is possible to carry out test methods as previously, without having to accept limitations in the execution of test sequences. When checking finished memory modules, for instance in customer return analysis, it is necessary to obtain comprehensive error information about the errors that have occurred in the memory circuit. With the provision of storage element 8, it is possible to supply this additional information which, in conjunction with the error information that is supplied in the test circuit 5, provides comprehensive information about the position of the defective memory cell.

It is necessary to utilize such a storage element 8 because not every error can be detected by simple writing and reading of the memory area. Many errors, particularly so-called soft errors, are only detectable under specific conditions such as those that can be generated with a test system. Because the appearance of an error after completion of the front end and back end test procedures is frequently an error that cannot be detected by previously utilized testing methods, it is necessary to carry out special test methods in the customer return analysis wherein the conditions of these methods are more strictly selected.

This testing method is carried out with the aid of the test circuit 5. However, in the execution of this test method, only redundancy-compliant error information is transmitted to the tester unit 12 by way of the output lines 10. Now the information that is additionally needed for precisely determining the position of the faulty memory cell is made available for reading in the storage element 8.

The storage element 8 is advantageously read as soon as the coding circuit 7 supplies the coded error information. It can thus be guaranteed that the memory cell address that is available in the storage element 8 is allocated to the same memory area as the coded error information.

Besides this, it is also possible for additional information about the type of error to be stored in the storage element 8. For instance, the stored information can indicate if there is a 0 in a memory cell that has just been read, even though a 1 was written into it, or if there is a 1 in the cell, though a 0 was written. This can be represented with the aid of an additional bit in the storage element 8.

FIG. 2 represents a table which indicates, for three different chip organizations, how to allocate the bits of a storage element 8 with 5 bits. The first row indicates how to allocate the five bits of the storage element for an x4 module, i.e. a memory module in which four data bits are assigned to each address. Which memory cell of the area indicated by the coded error information is defective, is coded in the first bit bit0 and the second bit bit1. Because the word line of the memory area in an x4 organization of the cell array is partitioned into four portions, it must be indicated by means of the third bit bit2 and the fourth bit bit3 which of the portions contains the faulty memory cell.

The fifth bit bit4 of the storage element 8 indicates the type of error of the defective memory cell. If a 0 is stored in the fifth bit bit4, then there is a 0 in the memory cell that is read, although this cell would contain a 1 if the cell were functioning correctly. A 1 in the fifth bit bit4 indicates that the memory cell contains a 1, though a 0 would be read given proper functioning. Of course, this coding can also be provided the other way around.

In an x8 memory module, an address contains eight data bits. Here, the redundancy-compliant compression also equals 1:16, so that the coded error information respectively indicates one address of an area with a size of 2×8 bits. In order to determine the position of the faulty cell, the position within the faulty area that is indicated by the coded error information is indicated in the first, second and third bits bit0, bit1, bit2. In an x8 memory module, there are two word line portions which are specified with the aid of the fourth bit3. The fifth bit bit4 indicates the type of error that has occurred.

In an x16 memory module, the first four bits indicate the position of the faulty memory cell in the faulty area, and the fifth bit bit4 indicates the type of error that has occurred.

The inventive method provides that the integrated memory circuit undergo a test procedure that, in the case of a return, for example, serves to find out whether the error reported by the customer actually exists. In case of an error that occurred after the completion of the production process, it is also necessary to find out what type of error it is in order to optimize the production method and/or the test procedures applied therein.

In summary, the novel method according to the invention provides a testing method whereby error information indicating whether at least one of the memory cells of an addressed memory area is faulty is generated during testing. This is performed with the aid of contemporary testing methods, for instance with the aid of a BIST circuit (Built-In Self-Test Circuit) which generates the addresses that are to be tested. Typically, such a test is carried out with the aid of a test circuit that is provided in the integrated memory circuit. If an error occurs, the test circuit is configured so that, on one hand, the coded error information is sent to the tester unit, and on the other hand, additional information about the position of the faulty memory cell in the area just tested is also stored in the storage element. This information is available in the storage element for transmission to the tester unit until the next error information is generated by the test circuit or until a subsequent error is detected in another memory area of the integrated memory circuit.

If the integrated memory circuit is now tested in the front end testing method or the back end testing method, this additional error information that is stored in the storage element is not needed and is therefore not read. If errors emerge over time in a memory module that was previously tested for errors, then a more precise indication of the position of the faulty memory cell is readable with the aid of the information that is additionally storable in the storage element, and consequently there is more information available in the customer return analysis from which to infer the cause of the error.

For instance, the possibility of signal couplings, leakage currents, and so on can be inferred from information about the precise position of the faulty memory cell and information about the configuration of the cells in the integrated memory circuit.

Of course, the storage element can be provided in almost any size in order to be able to store information not only about the position of one defective memory cell but about several defective cells in a memory area.

An advantage brought about by the present invention is the ability to correlate the errors with exact addresses.

We claim:

1. An integrated memory circuit, comprising:
a memory cell array formed with memory areas each having a plurality of cells; and
a test circuit connected to said memory cell array and configured to generate error information during testing of a respectively addressed memory area, the error information indicating if at least one of the cells of the addressed memory area is faulty;
a storage element for storing information identifying a faulty memory cell of the faulty memory area given an occurrence of an error in the addressed memory area.

2. The integrated memory circuit according to claim 1, wherein the information indicates a memory cell address of the faulty memory cell in the faulty memory area.

3. The integrated memory circuit according to claim 2, wherein the information indicates the addresses of a plurality of faulty memory cells.

4. The integrated memory circuit according to claim 1, wherein the information includes error type information indicating a type of error that has occurred in the faulty memory cell.

5. The integrated memory circuit according to claim 1, wherein said storage element is connected to be readable by an externally prescribed signal.

6. A method for testing an integrated memory circuit having a memory cell array and a test circuit, and the cell array having memory areas each encompassing a number of cells, the method which comprises:
addressing a memory area for testing the memory cell array;
generating error information indicating whether at least one of the cells of the addressed memory area is faulty; and
storing information identifying a faulty memory cell of the faulty memory area given the occurrence of an error in the addressed memory area.

7. The method according to claim 6, which comprises reading the information.

8. The method according to claim 6, which comprises generating and storing information indicating what type of error has occurred.
